(19) United States
(12) Patent Application Publication
(10) Pub. No.: US 2025/0157508 A1
(43) Pub. Date: May 15, 2025

(54) MEMORY DEVICE AND COMPUTATION METHOD THEREOF

(71) Applicant: MACRONIX INTERNATIONAL CO., LTD., Hsinchu (TW)

(72) Inventors: Huai-Mu WANG, New Taipei City (TW); Han-Wen HU, Zhubei City (TW); Yung-Chun LI, New Taipei City (TW); Bo-Rong LIN, Taichung City (TW)

(21) Appl. No.: 18/641,578

(22) Filed: Apr. 22, 2024

Related U.S. Application Data
(60) Provisional application No. 63/548,542, filed on Nov. 14, 2023.

(51) Int. Cl. G11C 7/10; G11C 7/12; G11C 7/16

(52) U.S. Cl. CPC G11C 7/1096; G11C 7/12; G11C 7/16

(57) ABSTRACT

The application discloses a memory device and a computation method thereof. A plurality of weight data are stored in a plurality of first memory cells of the memory device. A plurality of input data are input via a plurality of string select lines. A plurality of memory cell currents are generated in the plurality of first memory cells based on the weight data and the input data. The memory cell currents are summed on a plurality of bit lines coupled to the plurality of string select lines to obtain a plurality of summed currents. The summed currents are converted into a plurality of analog-to-digital conversion results. The plurality of analog-to-digital conversion results are accumulated to obtain a computational result.

This application claims the benefit of U.S. provisional application Ser. No. 63/548,542, filed Nov. 14, 2023, the disclosure of which is incorporated by reference herein in its entirety.

### TECHNICAL FIELD

The disclosure relates in general to a memory device and a computation method thereof.

### BACKGROUND

In recent years, there have been many new researches and innovative methods for large-scale approximate nearest neighbor search, including partition-based, graph-based indexing strategies, or machine learning.

Indexing strategy refers to the technical methods used in databases or data structures to accelerate data retrieval and queries. Indexing is a way of structuring data for faster access and retrieval. Indexing strategies include various techniques and algorithms such as partition indexing, B-tree indexing, hash indexing, etc. Choosing the most suitable indexing structure and algorithm according to the characteristics of the data and usage scenarios can improve the efficiency and performance of data retrieval.

It is now known that the computational space between accelerators and solid-state drives (SSDs) can be utilized to reduce the memory wall problem in large-scale datasets.

The memory wall refers to the phenomenon in computer systems where the speed difference between the processor and memory is increasingly significant. With the continuous improvement of processor performance, the number and speed of instructions that the processor can execute far exceed the speed at which memory can provide data. Therefore, the processor stalls while waiting to retrieve data from memory, leading to overall performance limitations, similar to hitting a “wall”. This situation is particularly significant when processing large-scale datasets because the limitation of memory speed becomes more apparent as the data size increases. Various methods such as increasing buffer memory, optimizing algorithms, and utilizing more efficient storage technologies are needed to address the memory wall problem.

Multiply Accumulate (MAC) operation is a fundamental mathematical operation, which involves multiplying two numbers and then adding the result to another number. In fields such as digital signal processing, neural networks, and matrix multiplication, MAC operations are commonly used. In neural networks, MAC operations are typically used to calculate the output of neurons. In MAC operations in neural networks, weights are multiplied by inputs, and then the results are accumulated to produce the final output.

Therefore, finding efficient and low-energy ways to perform operations such as MAC operations in neural networks using memory devices is an important focus for the industry.

### SUMMARY

According to one embodiment, a computational method for a memory device is provided. The computational method includes: storing a plurality of weight data in a plurality of first memory cells of the memory device; inputting a plurality of input data via a plurality of first string select lines; generating a plurality of memory cell currents in the plurality of first memory cells based on the weight data and the input data; summing the memory cell currents on a plurality of bit lines coupled to the plurality of first string select lines to obtain a plurality of summed currents; converting the summed currents into a plurality of analog-to-digital conversion results; and accumulating the plurality of analog-to-digital conversion results to obtain a computational result.

According to another embodiment, a memory device is provided. The memory device includes: a plurality of first memory cells storing a plurality of weight data; a plurality of first string select lines coupled to the plurality of first memory cells; a plurality of bit lines coupled to the plurality of first string select lines; a plurality of converters coupled to the plurality of bit lines; and an accumulator coupled to the plurality of converters. The plurality of input data are inputted via the plurality of first string select lines. A plurality of memory cell currents are generated in the plurality of first memory cells based on the weight data and the input data. The memory cell currents are summed on the plurality of bit lines to obtain a plurality of summed currents. The converters convert the plurality of summed currents into a plurality of analog-to-digital conversion results. The accumulator accumulates the plurality of analog-to-digital conversion results to obtain a computational result.

### BRIEF DESCRIPTION OF THE DRAWINGS

FIG. 1 depicts a schematic diagram of a memory device according to an embodiment of the present disclosure.

FIG. 2 depicts the computation flow of the memory device according to an embodiment of the present disclosure.

FIG. 3 depicts the operation flow of the memory device according to another embodiment of the present disclosure.

FIGS. 4A and 4B depict a schematic diagram of MAC operation according to an embodiment of the present disclosure.

FIG. 5 depicts an MAC operation of a memory device according to an embodiment of the present disclosure.

FIGS. 6A to 6D illustrate MAC operations of the memory device according to an embodiment of the present disclosure.

FIG. 7 illustrates the floor plane of the memory device during MAC operation according to an embodiment of the present disclosure.

FIGS. 8A and 8B illustrate the circuit and logic design during MAC operation of the memory device according to an embodiment of the present disclosure.

FIGS. 9A to 9E illustrate a schematic diagram of MAC operation of the memory device according to another embodiment of the present disclosure.

FIG. 10 illustrates the floor plane of the memory device during MAC operation according to the embodiment shown in FIGS. 9A to 9E.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

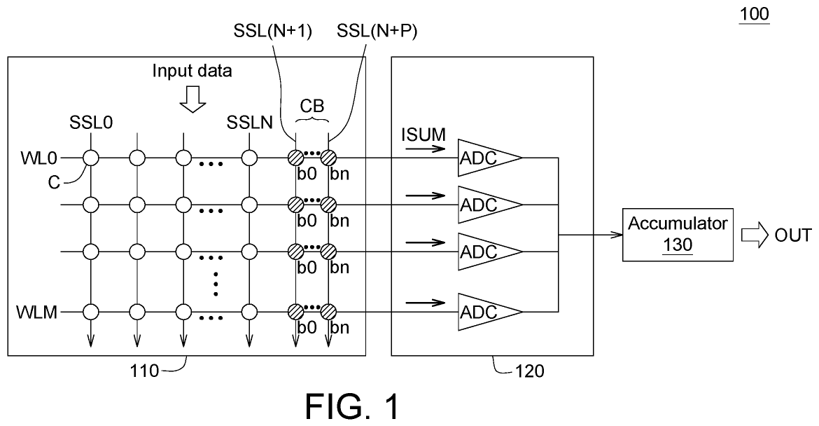

FIG. 1 depicts a schematic diagram of a memory device according to an embodiment of the present disclosure. As shown in FIG. 1, the memory device 100 according to an embodiment of the present disclosure includes at least: a memory array 110, a conversion circuit 120, and an accumulator (or an aggregator) 130. The memory array 110 is coupled to the conversion circuit 120. The conversion circuit 120 is coupled to the accumulator 130. The memory array 110 includes a plurality of memory cells C. These memory cells C are located at the intersection of word lines WL0-WLM (where M is a positive integer) and string select lines SSL0-SSLN (where N is a positive integer). In addition, to compensate for noise that may occur during analog operations, compensation biases b0-bn are stored in the memory cells coupled to the string select lines SSL (N+1) and SSL (N+P) (where P is a positive integer). The compensation biases b0-bn have multiple levels. In one embodiment, the memory cells storing the compensation biases b0-bn may differ from the memory cells receiving input data. For example, in one possible example, the memory cells receiving input data could be single-level cells (SLC), while the memory cells storing the compensation biases b0-bn could be multi-level cells (MLC). Alternatively, in another possible example, the memory cells receiving input data could be single-level cells (SLC), and the memory cells storing the compensation biases b0-bn could also be single-level cells (SLC), but multiple single-level cells are combined to store any one of the compensation biases b0-bn. During MAC operations, these memory cells C are written with weights, and input data is input to these memory cells C through the string select lines SSL0-SSLN. During MAC operations, taking word line WL0 as an example, the first row of memory cells C on word line WL0 receives input data (i.e., weights multiplied by input data) through the string select lines SSL0-SSLN. Based on the input data and the weights stored in the memory cells C, these memory cells C generate (analog) memory cell currents which are summed into the summation current ISUM on the bit lines. This summation current ISUM is input to the conversion circuit 120.

The conversion circuit 120 includes a plurality of analog-to-digital converters (ADCs). These ADCs convert the current ISUM into analog-to-digital conversion results by analog-to-digital conversion.

The accumulator 130 receives and accumulates a plurality of analog-to-digital conversion results generated by the ADCs of the conversion circuit 120 to obtain a digital output result OUT. The digital output result OUT is the result of the MAC operation of the input data and the weight data. The accumulator 130 may be implemented by a chip, a circuit block in the chip, a firmware circuit, a circuit board having several electronic elements and wires. Still further, foregoing mainly describes the solutions provided in the embodiments of the application. It may be understood that, to implement the foregoing functions, the accumulator 130 includes corresponding hardware structures and/or software modules for performing the functions. A person skilled in the art should easily be aware that, in combination with units and algorithm steps of the examples described in the embodiments disclosed in this specification, this application may be implemented in a hardware form or in a form of combining hardware with computer software. Whether a function is performed by hardware or hardware driven by computer software depends on particular applications and design constraints of the technical solutions. A person skilled in the art may use different methods to implement the described functions for each particular application, but it should not be considered that the implementation goes beyond the scope of this application.

In one embodiment of the application, the accumulator 130 may be divided into function modules based on the foregoing method examples. For example, each function module may be obtained through division based on each corresponding function, or two or more functions may be integrated into one processing module. The integrated module may be implemented in a form of hardware, or may be implemented in a form of a software function module. It should be noted that, in the embodiments of this application, division into modules is an example, and is merely logical function division. During actual implementation, another division manner may be used.

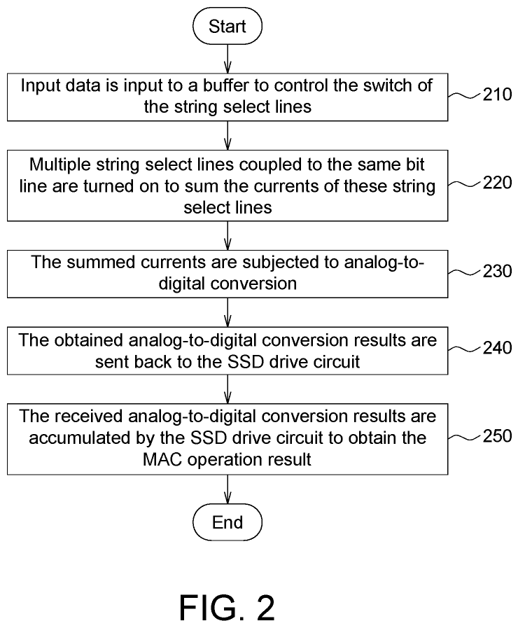

FIG. 2 depicts the computation flow of the memory device according to an embodiment of the present disclosure. In step 210, input data is input to a buffer (not shown) to control the switch of the string select lines.

In step 220, multiple string select lines coupled to the same bit line are turned on to sum the currents of these string select lines.

In step 230, the summed currents are subjected to analog-to-digital conversion. Steps 210-230 are performed within the memory array.

In step 240, the obtained analog-to-digital conversion results are sent back to the SSD (solid-state drive) drive circuit. Step 240 is performed by the finite state machine (FSM) of the memory device.

In step 250, the received analog-to-digital conversion results are accumulated by the SSD drive circuit to obtain the MAC operation result. Step 250 is performed by the SSD drive circuit.

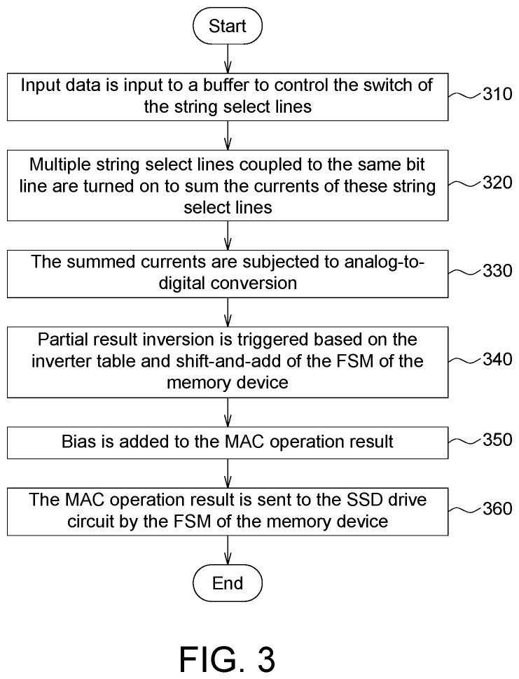

FIG. 3 depicts the operation flow of the memory device according to another embodiment of the present disclosure. In step 310, input data is input to a buffer (not shown) to control the switch of the string select lines.

In step 320, multiple string select lines coupled to the same bit line are turned on to sum the currents of these string select lines.

In step 330, the summed currents are subjected to analog-to-digital conversion. Steps 310-330 are performed within the memory array.

In step 340, partial result inversion is triggered based on the inverter table and shift-and-add of the FSM of the memory device.

In step 350, bias is added to the MAC operation result.

In step 360, the MAC operation result is sent to the SSD drive circuit by the FSM of the memory device. Steps 340-360 are performed by the finite state machine of the memory device.

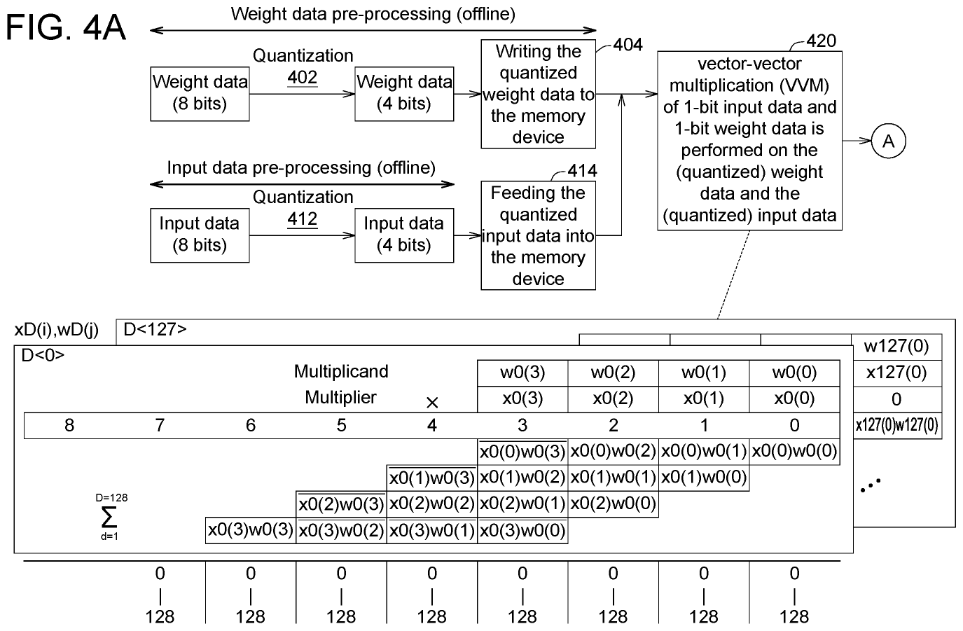

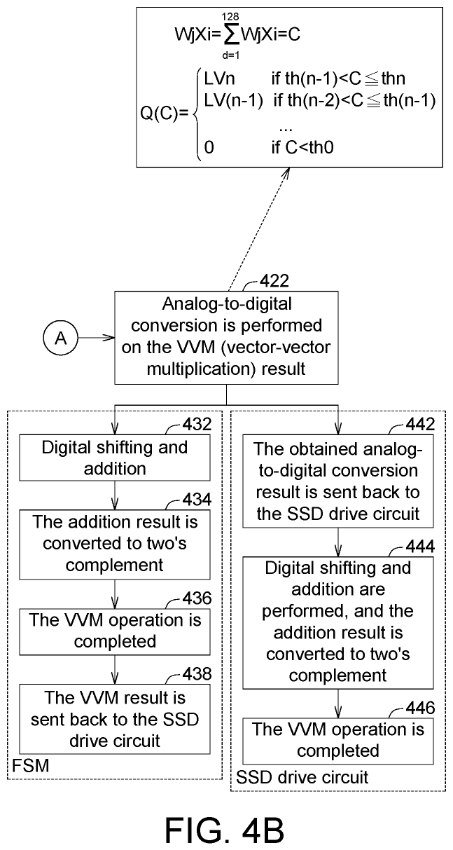

FIGS. 4A and 4B depict a schematic diagram of MAC operation according to an embodiment of the present disclosure. As shown in FIG. 4, in the MAC operation according to an embodiment of the present disclosure, the weight data (e.g., originally 8 bits) can undergo quantization step 402 to obtain weight data with fewer bits (e.g., 4 bits). In step 404, the quantized weight data is written to the memory device. In this embodiment, preprocessing of the weight data (quantization step 402) can be offline processing.

The input data (e.g., originally 8 bits) can undergo quantization step 412 to obtain input data with fewer bits (e.g., 4 bits). In step 414, the quantized input data is fed into the memory device (e.g., via string select lines SSL to input into the memory device). In this embodiment, preprocessing of the input data (quantization step 412) is online processing.

In step 420, vector-vector multiplication (VVM) of 1-bit input data and 1-bit weight data can be performed on the (quantized) weight data and the (quantized) input data.

The details of step 420 are as follows. Here, the explanation is based on weight data and input data with 128 dimensions which is not to limit the application. At dimension 0 D<0>, weight data w0=w0(3), w0(2), w0(1), w0(0) and input data x0=x0(3), x0(2), x0(1), x0(0). The rest can be extrapolated accordingly. Therefore, the multiplication of weight data and input data can be represented as: w0*x0=(w0(3), w0(2), w0(1), w0(0))*(x0(3), x0(2), x0(1), x0(0))=x0(3) w0(3)+x0(3) w0(2)+x0(3) w0(1)+x0(3) w0(0)+x0(2) w0(3)+x0(2) w0(2)+x0(2) w0(1)+x0(2) w0(0)+x0(1) w0(3)+x0(1) w0(2)+x0(1) w0(1)+x0(1) w0(0)+x0(0) w0(3)+x0(0) w0(2)+x0(0) w0(1)+x0(0) w0(0). The multiplication of other dimensions can be extrapolated accordingly. In FIG. 4, x̅₀̅₍̅₃̅₎̅w̅₀̅₍̅₂̅₎̅ represents the inversion of x0(3) w_0(2). XD(i) represents the i-th bit of dimension D of input data X (where D is a positive integer and i is a positive integer). WD(j) represents the j-th bit of dimension D of weight data W (where D is a positive integer and j is a positive integer).

In step 422, analog-to-digital conversion is performed on the VVM (vector-vector multiplication) result. Step 422 corresponds to step 230 in FIG. 2 and step 330 in FIG. 3. Here, the ADC conversion, for example but not limited to, performing MAC operation on weight Wj and input data Xi, can be represented as the following equation:

$${W}_{j} {X}_{i} = {\sum }_{d = 1}^{128} {W}_{j} \times {X}_{i} = C$$

In the above equation, the example provided considers weight and input data with 128 dimensions, but initially, this disclosure is not limited to this.

The quantized result Q(C) of the MAC result C can be represented as follows:

$$Q ( C ) = \{ \begin{matrix}L {V}_{n} & when t {h}_{n - 1} < C \leq t {h}_{n} \\ L {V}_{n - 1} & when t {h}_{n - 2} < C \leq t {h}_{n - 1} \\ & … \\ 0 & if C < t {h}_{0}\end{matrix}$$

In this context, LV represents the level, and “th” represents the threshold value. That is, if the MAC result C is less than the threshold value th_0, then Q(C)=0, and so on.

In an embodiment of the present disclosure, for the result of step 422, subsequent operations can be performed by the FSM (steps 432-438) or by the SSD drive circuit (steps 442-446).

In step 432, digital shifting and addition are performed.

In step 434, the addition result from step 432 is converted to two's complement.

In step 436, the VVM operation is completed.

In step 438, the VVM result is sent back to the SSD drive circuit. Steps 432-438 are completed by the FSM. Alternatively, steps 432-438 can be equivalent to steps 340-360.

In step 442, the obtained analog-to-digital conversion result is sent back to the SSD drive circuit.

In step 444, digital shifting and addition are performed, and the addition result is converted to two's complement.

In step 446, the VVM operation is completed.

Steps 442-446 are completed by the SSD drive circuit. Alternatively, steps 442-446 can be equivalent to steps 240-250.

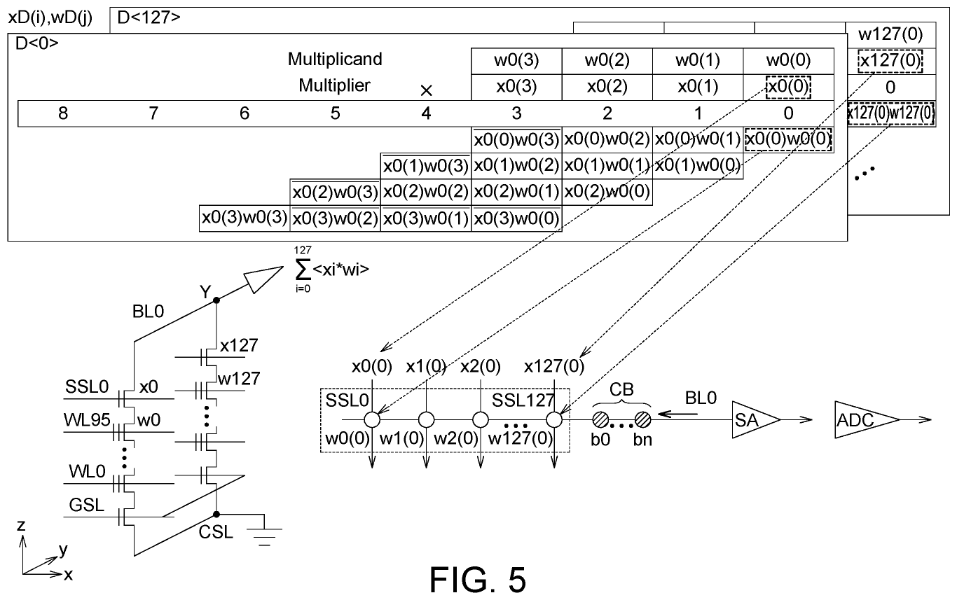

FIG. 5 depicts an MAC operation of a memory device according to an embodiment of the present disclosure. In this embodiment, weights w0(0), w1(0), . . . , w127(0) are programmed into the memory cells on word line WL95. Similarly, weights w0(1), w1(1), . . . , w127(1) are programmed into the memory cells on word line WL94 (not shown). The weight “wi(j)” represents i-th(2ⁱ) bit level and j-th dimension. Additionally, input data x0(0), x1(0), . . . , x127(0) are input to these memory cells via the string select lines SSL0-SSL127. Likewise, in the next cycle, input data x0(1), x1(1), . . . , x127(1) are input to these memory cells via the string select lines SSL0-SSL127. The input data “Xi(j)” represents i-th(2ⁱ) bit level and j-th dimension. In FIG. 5, GSL represents the global source line, and CSL represents the common source line. Input data x0(0), x1(0), . . . , x127(0) can also be referred to as the first part of the input data, while input data x0(1), x1(1), . . . , x127(1) can be referred to as the second part of the input data, and so forth.

In FIG. 5, it can be observed that the cell currents outputted by these memory cells are summed on the bit line (such as BL0) to form the summed current (like ISUM in FIG. 1), which is then input to the ADC.

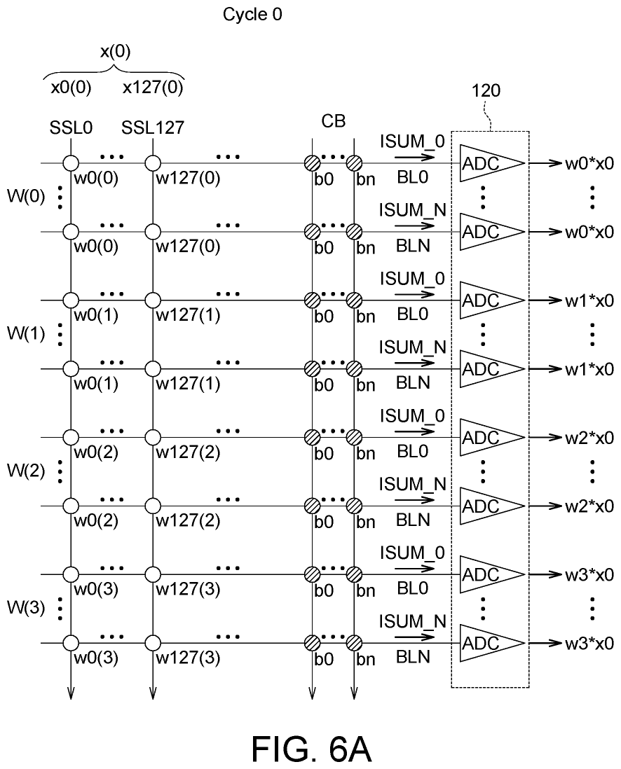

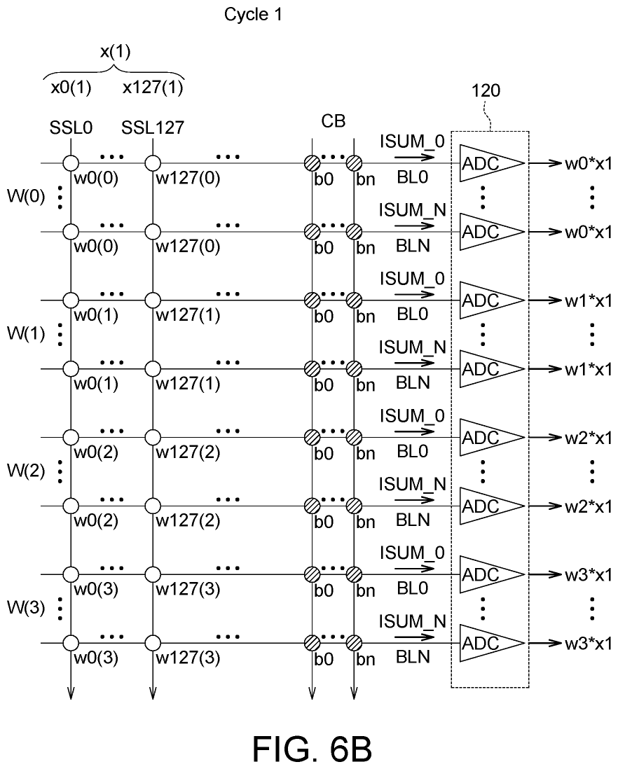

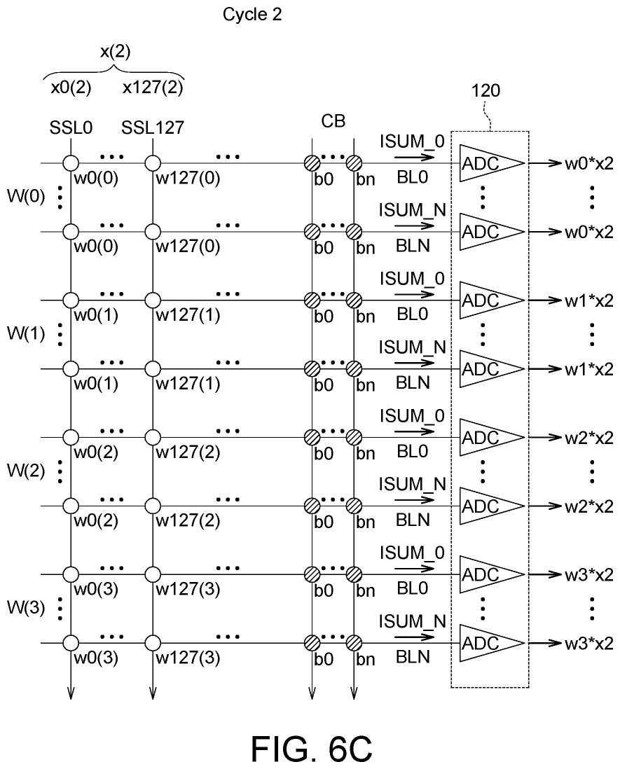

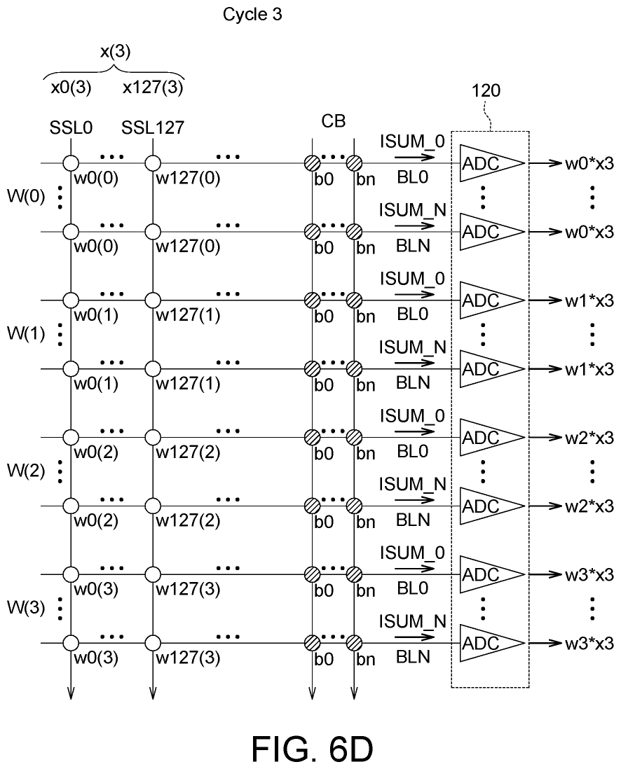

FIGS. 6A to 6D illustrate MAC operations of the memory device according to an embodiment of the present disclosure. In this embodiment, a MAC operation is completed over multiple cycles. Here, an explanation is provided using the example of completing a MAC operation over four cycles, but it should be understood that the present disclosure is not limited to this. In FIGS. 6A to 6D, CB represents compensation bias.

In FIG. 6A, during MAC operation, in cycle 0, input data x(0) (x(0)=x0(0), x1(0), . . . , x127(0)) is input to the memory cells via the string select lines SSL0-SSL127. Consequently, through bit lines BL0-BLN and ADC, w0*x0, . . . , w0*x0, w1*x0, . . . , w1*x0, w2*x0, . . . , w2*x0, w3*x0, . . . , w3*x0 can be obtained. Here, w0*x0=w0(0)*x0(0)+w1 (0)*x1(0)+ . . . +w127(0)*x127(0), and so on.

In FIG. 6B, during MAC operation, in cycle 1, input data x(1) (x(1)=x0(1), x1(1), . . . , x127(1)) is input to the memory cells via the string select lines SSL0-SSL127. Consequently, through bit lines BL0-BLN and ADC, w0*x1, . . . , w0*x1, w1*x1, . . . , w1*x1, w2*x1, . . . , w2*x1, w3*x1, . . . , w3*x1 can be obtained. Here, w0*x1=w0(0)*x0(1)+w1 (0)*x1(1)+ . . . +w127(0)*x127(1), and so on.

In FIG. 6C, during MAC operation, in cycle 2, input data x(2) (x(2)=x0(2), x1(2), . . . , x127(2)) is input to the memory cells via the string select lines SSL0-SSL127. Consequently, through bit lines BL0-BLN and ADC, w0*x2, . . . , w0*x2, w1*x2, . . . , w1*x2, w2*x2, . . . , w2*x2, w3*x2, . . . , w3*x2 can be obtained. Here, w0*x2=w0(0)*x0(2)+w1 (0)*x1(2)+ . . . +w127(0)*x127(2), and so on.

In FIG. 6D, during MAC operation, in cycle 3, input data x(3) (x(3)=x0(3), x1(3), . . . , x127(3)) is input to the memory cells via the string select lines SSL0-SSL127. Consequently, through bit lines BL0-BLN and ADC, w0*x3, . . . , w0*x3, w1*x3, . . . , w1*x3, w2*x3, . . . , w2*x3, w3*x3, . . . , w3*x3 can be obtained. Here, w0*x3=w0(0)*x0(3)+w1 (0)*x1(3)+ . . . +w127(0)*x127(3), and so on.

Therefore, after four cycles, a MAC operation can be completed using the above method. The cumulative result outputted by the accumulator 130 is the product sum of w0(0)*x0(0)+w0(1)*x0(0)+ . . . w127(3)*x127(3).

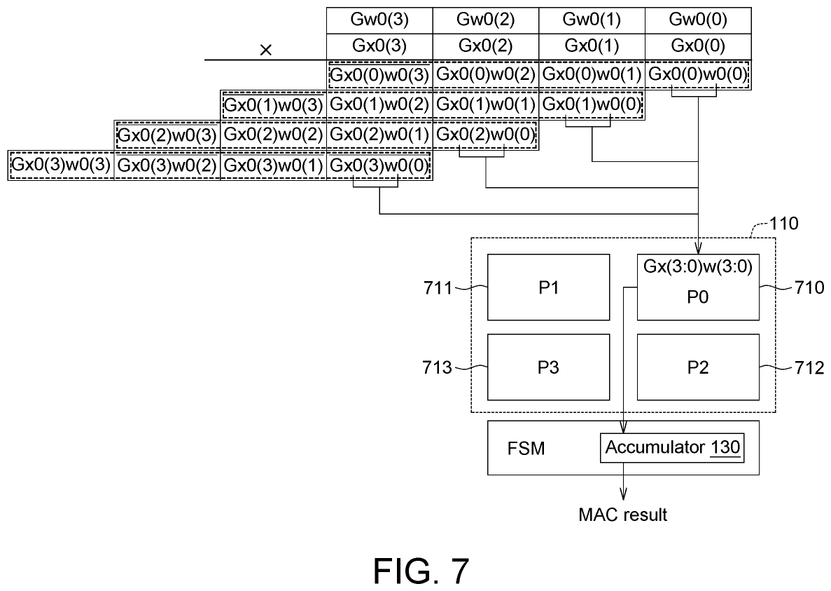

FIG. 7 illustrates the floor plane of the memory device during MAC operation according to an embodiment of the present disclosure. As shown in FIG. 7, the memory array 110 is divided into multiple planes 710, 711, 712, and 713 for explanation, but it should be understood that the present disclosure is not limited to this. Planes 710, 711, 712, or 713 can be similar to the circuit diagrams shown in FIGS. 6A to 6D. In other words, the circuit diagrams in FIGS. 6A to 6D can be considered as depicting planes 710 (or 711, 712, or 713).

For ease of explanation, during MAC operations involving weight data and input data, Gw(0)=w0(0), w1(0), . . . w127(0); Gx(0)=x0(0), x1(0), . . . x127(0), and so forth.

Therefore, as shown in FIG. 7, in cycle 0, the plane 710 performs the calculation of Gw(3:0)*Gx(0); in cycle 1, the plane 710 performs the calculation of Gw(3:0)*Gx(1); in cycle 2, the plane 710 performs the calculation of Gw(3:0)*Gx(2), and in cycle 3, the plane 710 performs the calculation of Gw(3:0)*Gx(3), where Gw(3:0)=Gw(0), Gw(1), Gw(2), Gw(3)

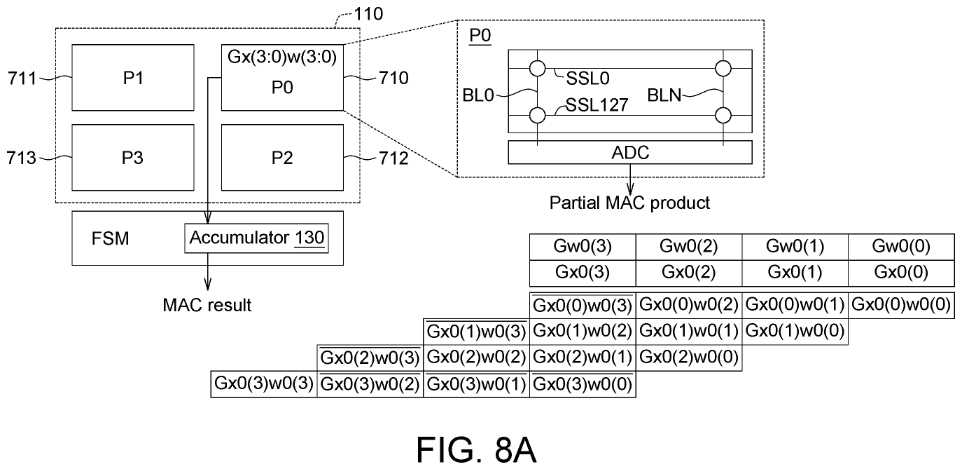

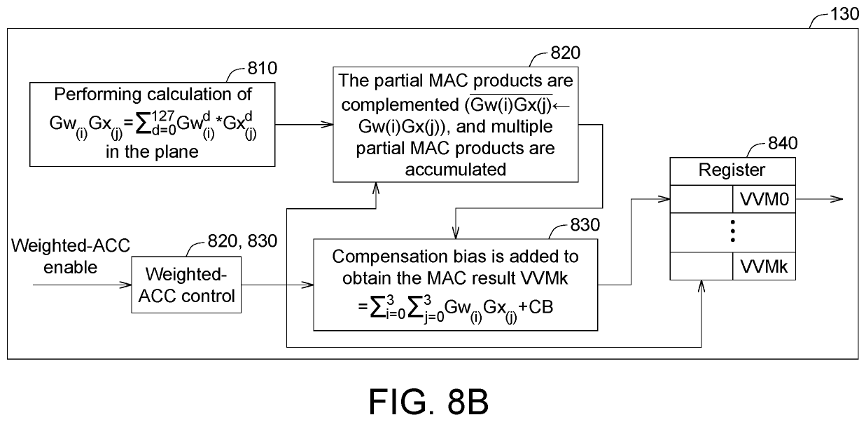

FIGS. 8A and 8B illustrate the circuit and logic design during MAC operation of the memory device according to an embodiment of the present disclosure. In this embodiment, the maximum number of the string select lines of the memory array determines the maximum dimension of the input data, and the number of the bit lines determines the maximum number of weight data. Each plane 710 to 713 outputs partial MAC products.

In FIGS. 8A and 8B, in step 810, the calculation of Gw₍ᵢ₎ Gx₍ⱼ₎=Σ_{d=0}¹²⁷Gw₍ᵢ₎^{d}*Gx₍ⱼ₎^{d} can be performed in the plane. The result obtained in step 810 can also be referred to as partial MAC products.

In step 820, the partial MAC products are complemented (Gw₍ᵢ₎ Gx₍ⱼ₎←Gw₍ᵢ₎ Gx₍ⱼ₎), and multiple partial MAC products are accumulated.

In step 830, compensation bias is added to the string select lines to obtain the MAC result VVMₖ=Σᵢ₌₀³Σⱼ₌₀³Gw₍ᵢ₎Gx₍ⱼ₎+CB.

In step 840, the obtained result is stored in a register.

In FIGS. 8A and 8B, the weight accumulation (ACC) control can be used to send control signals to various functional blocks.

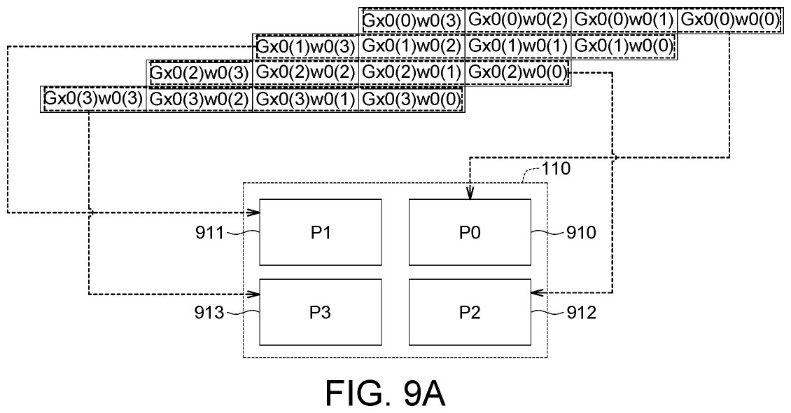

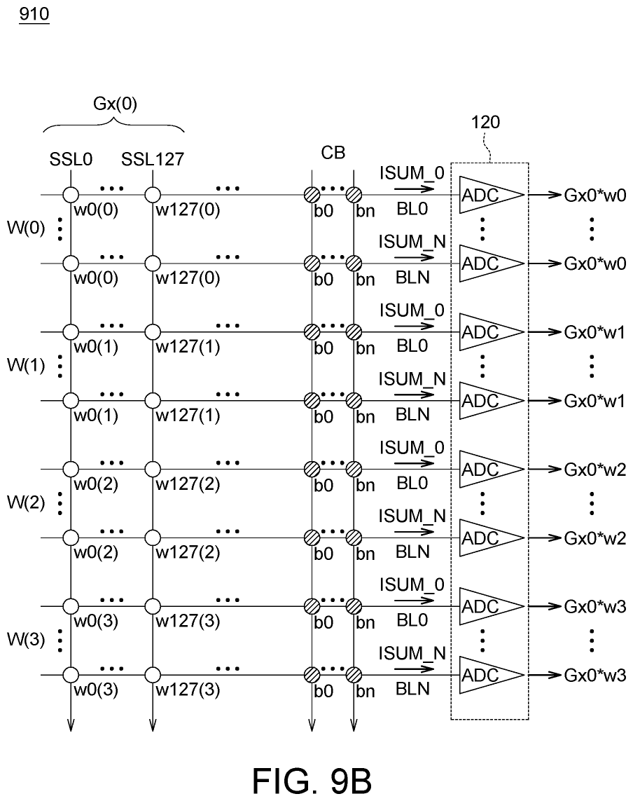

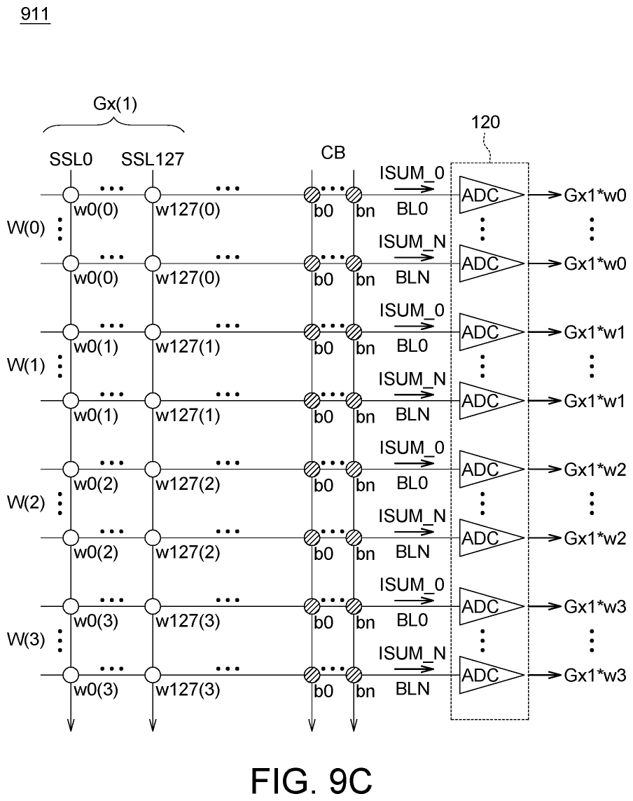

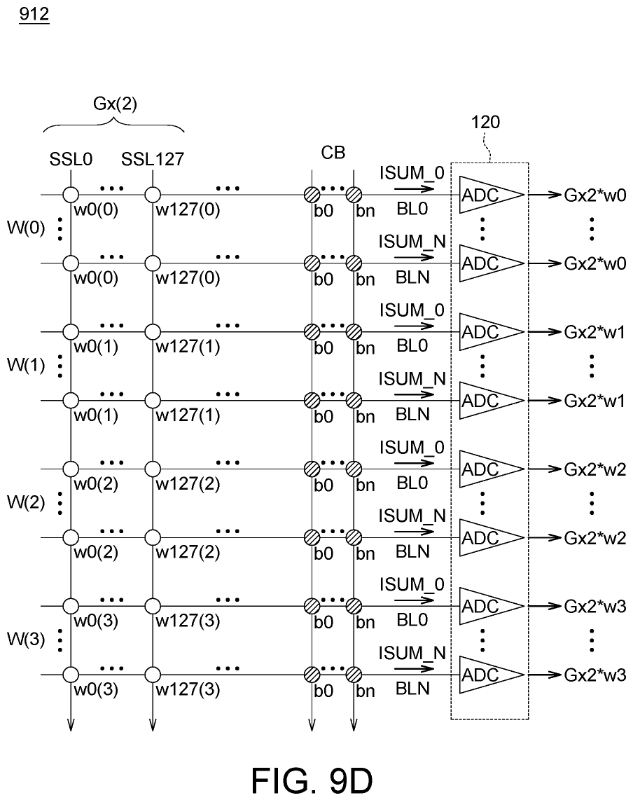

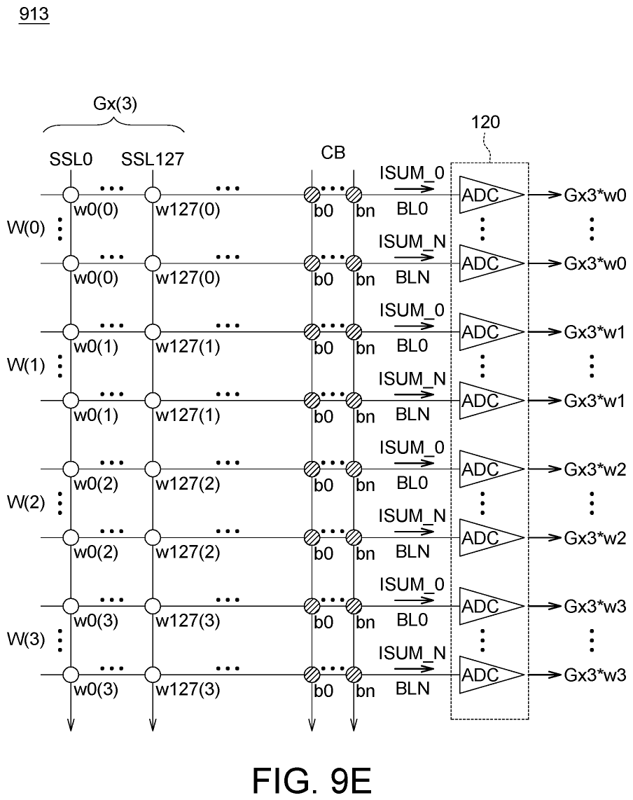

FIGS. 9A to 9E illustrate a schematic diagram of MAC operation of the memory device according to another embodiment of the present disclosure. In FIGS. 6A to 6D, MAC operations are completed over multiple cycles using a single plane. Conversely, in FIGS. 9A to 9E, MAC operations are completed within the same single cycle using multiple planes (for example, but not limited to, 4 planes). As shown in FIGS. 9A to 9E, the plane 910 is used to compute Gx(0)*W(0), Gx(0)*W(1), Gx(0)*W(2), Gx(0)*W(3) within the same single cycle (for example but not limited by, the cycle 0); the plane 911 is used to compute Gx(1)*W(0), Gx(1)*W(1), Gx(1)*W(2), Gx(1)*W(3) within the same single cycle (for example but not limited by, the cycle 0); the plane 912 is used to compute Gx(2)*W(0), Gx(2)*W(1), Gx(2)*W(2), Gx(2)*W(3) within the same single cycle (for example but not limited by, the cycle 0); and the plane 913 is used to compute Gx(3)*W(0), Gx(3)*W(1), Gx(3)*W(2), Gx(3)*W(3) within the same single cycle (for example but not limited by, the cycle 0).

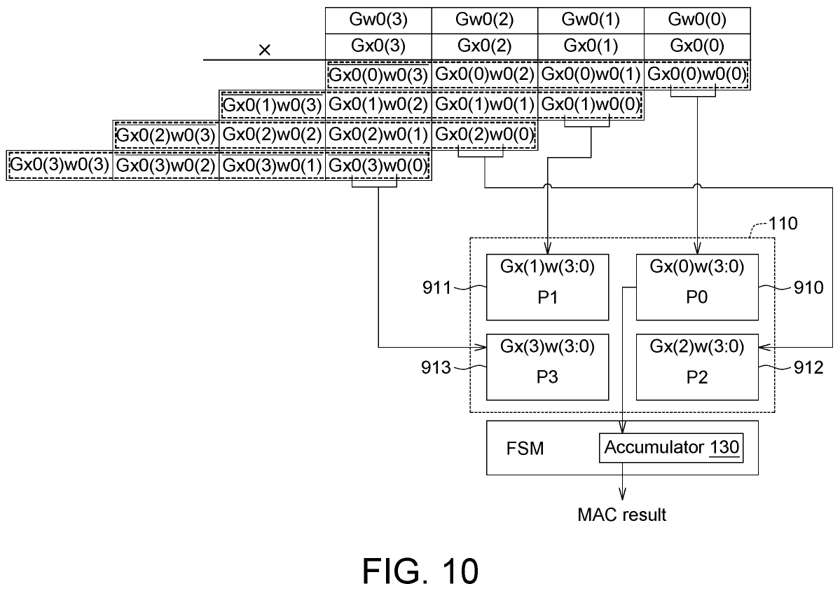

FIG. 10 illustrates the floor plane of the memory device during MAC operation according to the embodiment shown in FIGS. 9A to 9E. As shown in FIG. 10, the memory array 110 is divided into multiple planes 910, 911, 912, and 913 for explanation, but it should be understood that the present disclosure is not limited to this. Planes 910, 911, 912, or 913 can be similar to the circuit diagrams shown in FIGS. 9A to 9E.

For ease of explanation, during MAC operations involving weight data and input data, Gw(0)=w0(0), w1(0), . . . w127(0); Gx(0)=x0(0), x1(0), . . . x127(0), and so forth.

Therefore, as shown in FIG. 10, within the same cycle, the plane 910 performs the computation of Gw(3:0)*Gx(0), the plane 911 performs the computation of Gw(3:0)*Gx(1), the plane 912 performs the computation of Gw(3:0)*Gx(2), and the plane 913 performs the computation of Gw(3:0)*Gx(3), where Gw(3:0)=Gw(0), Gw(1), Gw(2), Gw(3).

In other words, in FIG. 10, the input data is sent to 4 planes via the string select lines to generate multiple partial MAC operation results in parallel within the same cycle, and these partial MAC operation results are accumulated by the accumulator 130.

In the disclosed embodiments, inputting data in parallel to the memory array via the string select lines achieves high computational efficiency. For example, with a dimension of 128, and input and weight data each being 4 bits, if the plane size is 16 KB and the number of planes is 4, the MAC speed is approximately 40 us with a power consumption of 200 mW. Then, the MAC operation of the disclosed embodiment achieves a throughput of 1 Tera Operations Per Second (TOPS) per watt, calculated as 524,288/16/40 us/200 mW*2*128=1 TOPS/w. Therefore, the memory device of the disclosed embodiment has high computational power.

The memory device and the computation method of the disclosed embodiment achieve analog MAC operations using memory devices. Compared to traditional digital MAC operations, the memory device and the computation method of the disclosed embodiment have wider calculation bandwidth and lower energy consumption.

The memory device and the computation method of the disclosed embodiment relate to a mapping mechanism for input data and weight data in analog MAC operations with storage planes (as shown in FIGS. 6A to 6D, or FIGS. 9A to 9E), combined with ADC and accumulators.

The memory device and the computation method of the disclosed embodiment are not limited to 4-bit 128-dimensional data vectors or matrices but also include various data formats for VVM/MAC operations.

The memory device and the computation method of the disclosed embodiment are applicable not only to 3D memory structures but also to 2D memory structures; for example, 2D/3D NAND flash memory, 2D/3D phase change memory (PCM), 2D/3D resistive random-access memory (RRAM), 2D/3D magnetoresistive random-access memory (MRAM), and so on.

The memory device and the computation method of the disclosed embodiment are applicable not only to non-volatile memory but also to volatile memory.

The memory device and the computation method of the disclosed embodiment can maximize the computational throughput of input vectors by utilizing string select lines of multiple memory planes.

The memory device and the computation method of the disclosed embodiment are applicable in environments such as analog VVM with data mapping, activating string select lines to sum analog currents on a single bit line, and page buffer-based ADC with accumulators.

In the disclosed embodiment, any multi-bit input multi-bit weight VVM can be decomposed into one-bit input one-bit weight VVM.

The memory device and the computation method of the disclosed embodiment can be applied in edge artificial intelligence applications, including computer vision processing and signal processing. In these scenarios, most memory devices utilize in-memory computing. The memory device and the computation method of the disclosed embodiment can be applied in, for example, AI fully connection layers with VVM/MAC calculations. Additionally, the memory device and the computation method of the disclosed embodiment can be applied in digital signal processing or image processing using general matrix multiplication (GEMM).

While this document may describe many specifics, these should not be construed as limitations on the scope of an invention that is claimed or of what may be claimed, but rather as descriptions of features specific to particular embodiments. Certain features that are described in this document in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made based on what is disclosed.

What is claimed is:

1. A computational method for a memory device, comprising:
storing a plurality of weight data in a plurality of first memory cells of the memory device;
inputting a plurality of input data via a plurality of first string select lines;
generating a plurality of memory cell currents in the plurality of first memory cells based on the weight data and the input data;
summing the memory cell currents on a plurality of bit lines coupled to the plurality of first string select lines to obtain a plurality of summed currents;
converting the summed currents into a plurality of analog-to-digital conversion results; and
accumulating the plurality of analog-to-digital conversion results to obtain a computational result.

2. The computational method for the memory device according to claim 1, further comprising:
storing a plurality of compensation biases in a plurality of second memory cells,
the plurality of compensation biases have multiple levels, and
the plurality of first memory cells are single-level cells (SLC), while the plurality of second memory cells are multi-level cells (MLC); or the plurality of first memory cells and the plurality of second memory cells are single-level cells (SLC), several second memory cells are combined to store any one of the plurality of compensation biases.

3. The computational method for the memory device according to claim 1, wherein
the memory device comprises at least one memory plane; and
within a plurality of cycles, the memory plane respectively receives a plurality of partial input data of the input data to obtain the computational result.

4. The computational method for the memory device according to claim 1, wherein
the memory device comprises a plurality of memory planes; and
within the same single cycle, the plurality of memory planes respectively receive a plurality of partial input data of the input data to obtain the computational result.

5. The computational method for the memory device according to claim 1, wherein
pre-processing the weight data offline to quantize the weight data; and
pre-processing the input data online to quantize the input data.

6. A memory device comprising:
a plurality of first memory cells storing a plurality of weight data;
a plurality of first string select lines coupled to the plurality of first memory cells;
a plurality of bit lines coupled to the plurality of first string select lines;
a plurality of converters coupled to the plurality of bit lines; and
an accumulator coupled to the plurality of converters,
wherein
the plurality of input data are inputted via the plurality of first string select lines;
a plurality of memory cell currents are generated in the plurality of first memory cells based on the weight data and the input data;
the memory cell currents are summed on the plurality of bit lines to obtain a plurality of summed currents;
the converters convert the plurality of summed currents into a plurality of analog-to-digital conversion results; and
the accumulator accumulates the plurality of analog-to-digital conversion results to obtain a computational result.

7. The memory device according to claim 6, wherein
a plurality of compensation biases are stored in a plurality of second memory cells,
the plurality of compensation biases have multiple levels, and
the plurality of first memory cells are single-level cells (SLC), while the plurality of second memory cells are multi-level cells (MLC); or the plurality of first memory cells and the plurality of second memory cells are single-level cells (SLC), several second memory cells are combined to store any one of the plurality of compensation biases.

8. The memory device according to claim 6, wherein
the memory device comprises at least one memory plane; and
within a plurality of cycles, the memory plane respectively receives a plurality of partial input data of the input data to obtain the computational result.

9. The memory device according to claim 6, wherein
the memory device comprises a plurality of memory planes, and
within the same single cycle, the plurality of memory planes respectively receive a plurality of partial input data of the input data to obtain the computational result.

10. The memory device according to claim 6, wherein
the weight data is pre-processed offline to quantize the weight data; and
the input data is pre-processed online to quantize the input data.
